(19) United States
(12) Patent Application Publication
(10) Pub. No.: US 2017/0105294 A1
(43) Pub. Date: Apr. 13, 2017

(54) ELECTRONIC APPARATUS

(71) Applicant: KYOCERA CORPORATION, Kyoto (JP)

(72) Inventors: Tetsuya SHIMODA, Kirishima-shi (JP); Mizuho HIDAKA, Kawasaki-shi (JP); Norikazu MORIOKA, Tokyo (JP)

(21) Appl. No.: 15/388,628

(22) Filed: Dec. 22, 2016

Related U.S. Application Data
(63) Continuation of application No. PCT/JP2015/068224, filed on Jun. 24, 2015.

(30) Foreign Application Priority Data
Jun. 26, 2014 (JP) 2014-131085

(51) Int. Cl. H05K 5/00; B06B 1/06; H01L 51/52; H01L 27/32; G06F 1/16; H05K 5/03

(52) U.S. Cl. CPC H05K 5/0017; G06F 1/1626; H05K 5/03; H01L 51/5237; H01L 27/3225; H01L 27/3262; B06B 1/06; G09G 3/3258

(57) ABSTRACT

An electronic apparatus is disclosed. An electronic apparatus comprises a cover panel, a display panel, and a piezoelectric vibrator. The cover panel is located on a front surface of the electronic apparatus. The display panel is located on a rear surface side of the cover panel and includes a display element that emits light itself. The piezoelectric vibrator is located closer to the rear surface side than the display panel is, is configured to be vibrated based on a sound signal, and outputs the vibration to the cover panel through the display panel.

### CROSS-REFERENCE TO RELATED APPLICATION

The present application is a continuation based on PCT Application No. PCT/JP2015/068224 filed on Jun. 24, 2015, which claims the benefit of Japanese Application No. 2014-131085, filed on Jun. 26, 2014. PCT Application No. PCT/JP2015/068224 is entitled “ELECTRONIC APPARATUS”, and Japanese Application No. 2014-131085 is entitled “ELECTRONIC APPARATUS”. The contents of which are incorporated by reference herein in their entirety.

### FIELD

Embodiments of the present disclosure relate to an electronic apparatus.

### BACKGROUND

Various technologies have conventionally been proposed for electronic apparatuses.

### SUMMARY

An electronic apparatus is disclosed. In one embodiment, an electronic apparatus comprises a cover panel, a display panel, and a vibrator. The cover panel is located on a front surface of the electronic apparatus. The display panel is located on a rear surface side of the cover panel and includes a display element that emits light itself. The vibrator is located closer to the rear surface side than the display panel is, is configured to be vibrated based on a sound signal, and outputs the vibration to the cover panel through the display panel.

### BRIEF DESCRIPTION OF THE DRAWINGS

FIG. 1 illustrates a perspective view showing an external appearance of an electronic apparatus.

FIG. 2 illustrates a front view showing the external appearance of the electronic apparatus.

FIG. 3 illustrates a rear view showing the external appearance of the electronic apparatus.

FIG. 4 illustrates a sectional structure of the electronic apparatus.

FIG. 5 illustrates a perspective view showing a cover panel, a display panel, and a piezoelectric vibrator when viewed from an inner main surface thereof.

FIG. 6 illustrates an electrical configuration of the electronic apparatus.

FIG. 7 illustrates a top view showing a structure of the piezoelectric vibrator.

FIG. 8 illustrates a side view showing the structure of the piezoelectric vibrator.

FIG. 9 illustrates how the piezoelectric vibrator vibrates while being bent.

FIG. 10 illustrates how the piezoelectric vibrator vibrates while being bent.

FIG. 11 illustrates a view for describing air conduction sound and tissue conduction sound.

FIG. 12 illustrates a schematic configuration of the display panel.

FIG. 13 illustrates a perspective view showing the sectional structure of the electronic apparatus.

FIG. 14 illustrates a plan view showing the display panel and the piezoelectric vibrator.

These and other objects, features, aspects and advantages of the present disclosure will become more apparent from the following detailed description of embodiments when taken in conjunction with the accompanying drawings.

### DETAILED DESCRIPTION

### First Embodiment

<External Appearance of Electronic Apparatus>

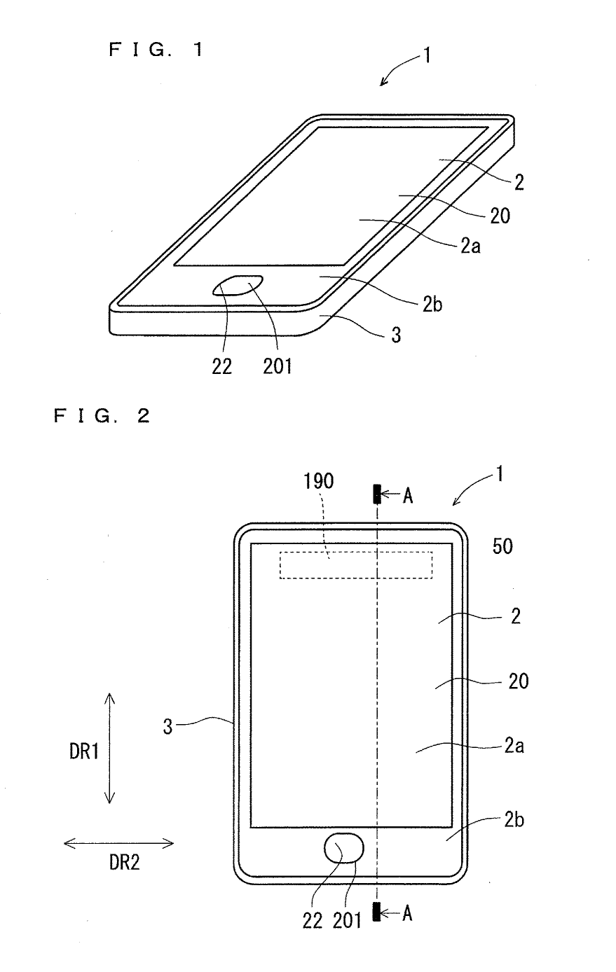

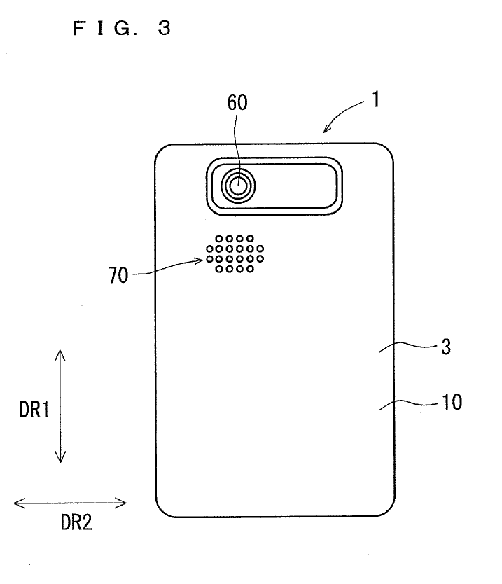

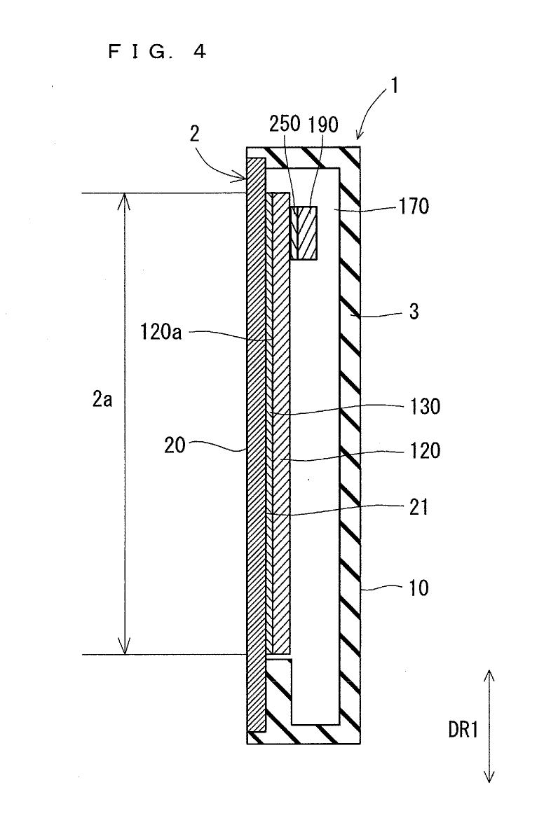

FIGS. 1 to 3 respectively illustrate a perspective view, a front view, and a rear view showing an external appearance of an electronic apparatus 1. FIG. 4 illustrates a schematic view showing a sectional structure taken along an A-A line of the electronic apparatus 1 illustrated in FIG. 2. The electronic apparatus 1 according to one embodiment is, for example, a mobile phone such as a smartphone.

As illustrated in FIGS. 1 to 4, the electronic apparatus 1 has a plate shape substantially rectangular in a plan view. The electronic apparatus 1 includes a cover panel 2 that is transparent and covers a display surface 120a of a display panel 120 (see FIG. 4) and a case 3 supporting the cover panel 2.

The cover panel 2 is located on a surface of the electronic apparatus 1, and more specifically, a front surface of the electronic apparatus 1. The cover panel 2 forms a front portion of the electronic apparatus 1 except for a peripheral end (peripheral portion) of the front portion of the electronic apparatus 1.

The cover panel 2 has, for example, a plate shape and a substantially rectangular shape in the plan view. The cover panel 2 has a first main surface 20 that forms part of the front surface of the electronic apparatus 1 and a second main surface 21 that is located opposite to the first main surface 20 and faces the display surface 120a of the display panel 120. Hereinafter, the first main surface 20 may be referred to as an “outer main surface 20”, and the second main surface 21 may be referred to as an “inner main surface 21”. The cover panel 2 may be a planar panel having a planar shape or a curved panel having a curved shape.

The cover panel 2 is made of, for example, sapphire. Here, sapphire refers to a monocrystal that contains alumina (Al₂O₃) as a main component, and herein, refers to a monocrystal having a purity of Al₂O₃ of approximately 90% or more. The purity of Al₂O₃ is preferably greater than or equal to 99% in order to further increase resistance to scratching. In addition, examples of materials for the cover panel 2 include diamond, zirconia, titania, crystal, lithium tantalite, and aluminum oxynitride. These materials are preferably a monocrystal having a purity of greater than or equal to approximately 90% in order to further increase resistance to scratching.

Although the cover panel 2 is a panel of a single-layer structure that includes a layer of sapphire located on the surface of the electronic apparatus 1 in one embodiment, the cover panel 2 may be a composite panel (laminated panel) of a multilayer structure that includes the layer of sapphire. For example, the cover panel 2 may be a laminated panel of a two-layer structure that includes a layer of sapphire (sapphire panel) located on the surface of the electronic apparatus 1 and a layer of glass (glass panel) attached to the layer of sapphire. The cover panel 2 may be a laminated panel of a three-layer structure that includes the layer of sapphire (sapphire panel) located on the surface of the electronic apparatus 1, the layer of glass (glass panel) attached to the layer of sapphire, and a layer of sapphire (sapphire panel) attached to the layer of glass.

The cover panel 2 has a transparent display portion (also referred to as a display window) 2a transmitting the display of the display panel 120. The display portion 2a has, for example, a rectangular shape in the plan view. The display panel 120 includes a display element that emits light itself, which will be described below. For example, the display panel 120 is an organic electroluminescent (EL) panel. The visible light output from the display panel 120 passes through the display portion 2a and is emitted to the outside of the electronic apparatus 1. The user can visually recognize information displayed on the display panel 120 through the display portion 2a from the outside of the electronic apparatus 1.

The major portion of a peripheral end (peripheral portion) 2b of the cover panel 2 that surrounds the display portion 2a is opaque and/or not transparent because of, for example, a film or the like that is attached thereto. Accordingly, the major portion of the peripheral end 2b is a non-display portion that does not transmit the display of the display panel 120.

The case 3 is formed in a substantially rectangular parallelepiped having one main surface partially open. The case 3 forms the peripheral end of the front portion, the side portion, and the back portion of the electronic apparatus 1. The case 3 is made of, for example, at least one of resin and metal. The resin forming the case 3 may be, for example, polycarbonate resin, ABS resin, and nylon resin. The metal forming the case 3 may be, for example, aluminum. The case 3 may be formed of only one member or a combination of a plurality of members.

As illustrated in FIG. 4, a touch panel 130 is attached to the inner main surface 21 of the cover panel 2. The display panel 120 being the display is attached to a main surface of the touch panel 130 opposite to a main surface thereof on the inner main surface 21 side. That is to say, the display panel 120 is installed on the inner main surface 21 of the cover panel 2 with the touch panel 130 therebetween. A portion of the cover panel 2 facing the display panel 120 is the display portion 2a. The user can provide various instructions to the electronic apparatus 1 by operating the display portion 2a of the cover panel 2 using the finger or the like.

A bonding material between the touch panel 130 and the cover panel 2 and a bonding material between the display panel 120 and the touch panel 130 may be, for example, a double-sided tape (such as an optical clear adhesive (OCA) tape) or an adhesive (photocurable resin such as optically clear resin (OCR)) that have high transmittance of the visible light.

A printed circuit board (not shown) is located in the case 3, various components such as a CPU 101 and a DSP 102, which will be described below, being installed on the printed circuit board.

An operation unit 200, which will be described below, is located in the case 3 and includes an operation button 201. The operation button 201 has the surface exposed from the lower-side end portion of the outer main surface 20 of the cover panel 2. A hole (through hole) 22 that penetrates the cover panel 2 in a thickness direction of the cover panel 2 is located in the lower-side end portion of the cover panel 2. The hole 22 is located in the central portion in the horizontal direction in the lower-side end portion of the cover panel 2. The operation button 201 is exposed from the hole 22. Although one operation button 201 is located for the operation unit 200 in one embodiment, a plurality of operation buttons 201 exposed from the cover panel 2 may be located. Alternatively, the operation button 201 may not be located. In this case, the cover panel 2 does not need to have the hole 22, and a hole is not formed in the cover panel 2 at all.

For example, glass or resin is used as a material for the operation button 201. Examples of materials for the operation button 201 include crystalline materials such as diamond, zirconia, titania, crystal, lithium tantalite, and aluminum oxynitride.

A rear imaging unit 170 and a piezoelectric vibrator 190, which will be described below, are located in the case 3.

A rear-surface-lens transparent part 60 is located on the rear surface 10 of the electronic apparatus 1. An imaging lens of the rear imaging unit 170 in the case 3 can be visually recognized from the outside of the rear-surface-lens transparent part 60. Speaker holes 70 are located in the rear surface 10 of the electronic apparatus 1.

The cover panel 2 is attached to the case 3 with a bonding material (not shown). Specifically, the inner main surface 21 of the cover panel 2 is attached to the case 3 with the bonding material therebetween. Accordingly, the inner main surface 21 of the cover panel 2 is supported by the case 3.

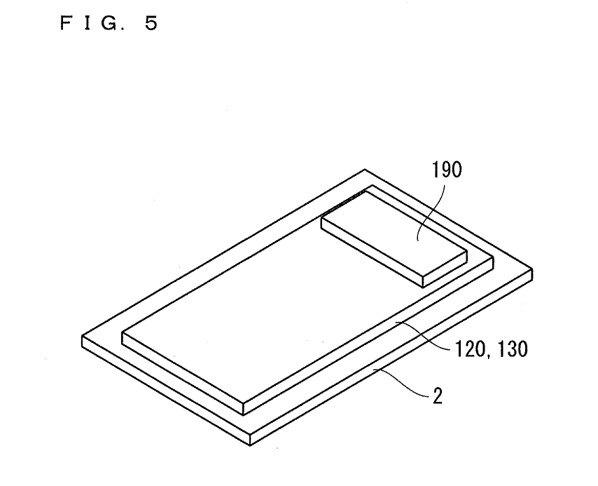

As illustrated in FIG. 4, the piezoelectric vibrator 190 is located closer to the rear surface side (the side opposite to the cover panel 2) than the display panel 120 is. FIG. 5 illustrates a perspective view schematically showing the cover panel 2, the touch panel 130, the display panel 120, and the piezoelectric vibrator 190 to make their positional relationships easy to see. The piezoelectric vibrator 190 is attached to the main surface of the display panel 120 on the rear surface side with, for example, a bonding material 250. The bonding material 250 may be, for example, the double-sided tape (such as the optical clear adhesive (OCA) tape) or the adhesive (such as the optically clear resin (OCR)). As described below, the piezoelectric vibrator 190 vibrates the cover panel 2 with the display panel 120 and the touch panel 130 therebetween. A voice is transmitted to the user by the vibration of the cover panel 2.

<Electrical Configuration of Electronic Apparatus>

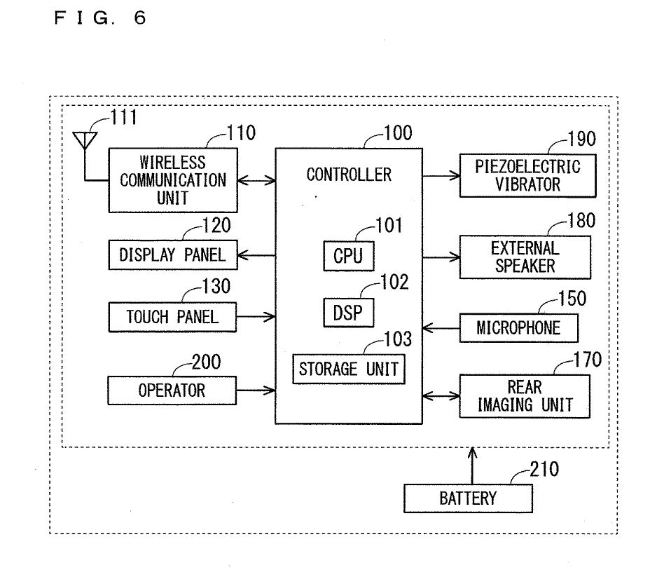

FIG. 6 illustrates a block diagram mainly showing the electrical configuration of the electronic apparatus 1. As illustrated in FIG. 6, the electronic apparatus 1 includes a controller 100, a wireless communication unit 110, the display panel 120, the touch panel 130, and a microphone 150. The electronic apparatus 1 further includes the rear imaging unit 170, an external speaker 180, the piezoelectric vibrator 190, the operation unit 200, and a battery 210. The case 3 accommodates the structural components, except for the cover panel 2, of the electronic apparatus 1.

The controller includes a Central Processing Unit (CPU) 101, a Digital Signal Processor (DSP) 102, and a storage unit 103. The controller 100 can manage the overall operation of the electronic apparatus 1 by controlling the other structural components of the electronic apparatus 1.

The storage unit 103 is a recording medium which is non-transitory such as a Read Only Memory (ROM) and a Random Access Memory (RAM) and is readable by the controller 100 (CPU 101 and DSP 102). A main program, a plurality of application programs, and the like are stored in the storage unit 103, the main program being a control program for controlling the electronic apparatus 1, specifically, for controlling the respective structural components such as the wireless communication unit 110 and the display panel 120 of the electronic apparatus 1. Various functions of the controller 100 can be enabled by the CPU 101 and the DSP 102 executing various programs in the storage unit 103.

Further, in addition to the ROM and RAM, the storage unit 103 may include a non-transitory recording medium, which is readable by a computer. The storage unit 103 may include, for example, a compact hard disk drive and a Solid State Drive (SSD).

The wireless communication unit 110 includes an antenna 111. In the wireless communication unit 110, the antenna 111 can receive a signal from a mobile phone different from the electronic apparatus 1, or from a communication device such as a web server connected to the Internet via a base station. The wireless communication unit 110 can perform an amplification process and down conversion on the received signal and output the signal to the controller 100. The controller 100 can perform demodulation processing or the like on the input signal, and acquire a sound signal (sound information) indicating a voice or music included in the received signal.

The wireless communication unit 110 can perform up-converting and the amplification process on a transmission signal including a sound signal or the like generated in the controller 100, and wirelessly transmit the transmission signal after the process from the antenna 111. The transmission signal from the antenna 111 can be received in a communication device connected to the Internet or a mobile phone different from the electronic apparatus 1 via the base station.

The display panel 120 is, for example, the organic EL panel. The display panel 120 can display various pieces of information such as characters, symbols, and graphics by control of the controller 100. The information displayed in the display panel 120 can be visually recognized by the user of the electronic apparatus 1 through the display portion 2a of the cover panel 2.

The touch panel 130 is, for example, a projection electrostatic capacitance touch panel having a sheet shape. The touch panel 130 can detect a contact of an object with respect to the display portion 2a of the cover panel 2 and output a detection signal corresponding to the detection result. The touch panel 130 is attached to the inner main surface 21 of the cover panel 2. The controller 100 can specify the details of the operation performed on the display portion 2a of the cover panel 2 based on the detection signal output from the touch panel 130 and perform a process according to the specified details.

The rear imaging unit 170 includes the imaging lens, an image sensor, and the like. The rear imaging unit 170 can image a still image and a moving image based on the control by the controller 100. The imaging lens of the rear imaging unit 170 can be visually recognized from the rear-surface-lens transparent part 60 located on the rear surface of the electronic apparatus 1. Therefore, the rear imaging unit 170 can image an object in front of the rear surface 10 side of the electronic apparatus 1.

The microphone 150 can convert a sound from the outside of the electronic apparatus 1 into an electric sound signal to output the signal to the controller 100. The sound from the outside of the electronic apparatus 1 is taken inside the electronic apparatus 1 through a microphone hole (not shown) located in the surface of the electronic apparatus 1 and is received by the microphone 150.

The external speaker 180 is, for example, a dynamic speaker. The external speaker 180 can convert the electric sound signal from the controller 100 into a sound and then output the sound. The sound output from the external speaker 180 is output from the speaker holes 70 located in the rear surface 10 of the electronic apparatus 1 to the outside. The volume of the sound output from the speaker holes 70 can be set to a degree such that the sound can be heard at a location apart from the electronic apparatus 1.

As described above, the piezoelectric vibrator 190 is located closer to the rear surface side (the side opposite to the cover panel 2) than the display panel 120 is. As exemplified in FIG. 4, the piezoelectric vibrator 190 is attached to the upper-side end portion of the display panel 120 with the bonding material 250 in the plan view. The piezoelectric vibrator 190 can be vibrated by a drive voltage applied from the controller 100. The controller 100 can generate a drive voltage based on a sound signal and apply the drive voltage to the piezoelectric vibrator 190. The sound signal is, for example, a voice signal from a mobile phone of the opposite party. The piezoelectric vibrator 190 is vibrated by the controller 100 based on the sound signal, so that the vibration is transmitted to the cover panel 2 through the display panel 120 and the touch panel 130, and the cover panel 2 vibrates based on the sound signal. A reception sound is accordingly transmitted from the cover panel 2 to the user. The volume of the reception sound can be set to a degree such that the user can appropriately hear the sound when moving the cover panel 2 close to an ear.

The operation unit 200 includes the operation button 201 and a switch (not shown) and can detect an operation performed on the operation button 201. In the operation unit 200, the switch turns ON when the operation button 201 is pressed (operated). When the switch turns ON, the operation unit 200 outputs an ON signal indicating that the operation button 201 has been operated to the controller 100. On the other hand, when the operation button 201 has not been operated and the switch is OFF, the operation unit 200 outputs an OFF signal indicating that the operation button 201 has not been operated to the controller 100. The controller 100 can determine the presence or absence of the operation performed on the operation button 201 based on the ON signal and the OFF signal received from the operation unit 200 and perform a process according to the determination result.

The battery 210 outputs a power source for the electronic apparatus 1. The power source output from the battery 210 is supplied to the respective electronic components such as the controller 100 and the wireless communication unit 110 of the electronic apparatus 1.

<Details of Piezoelectric Vibrator>

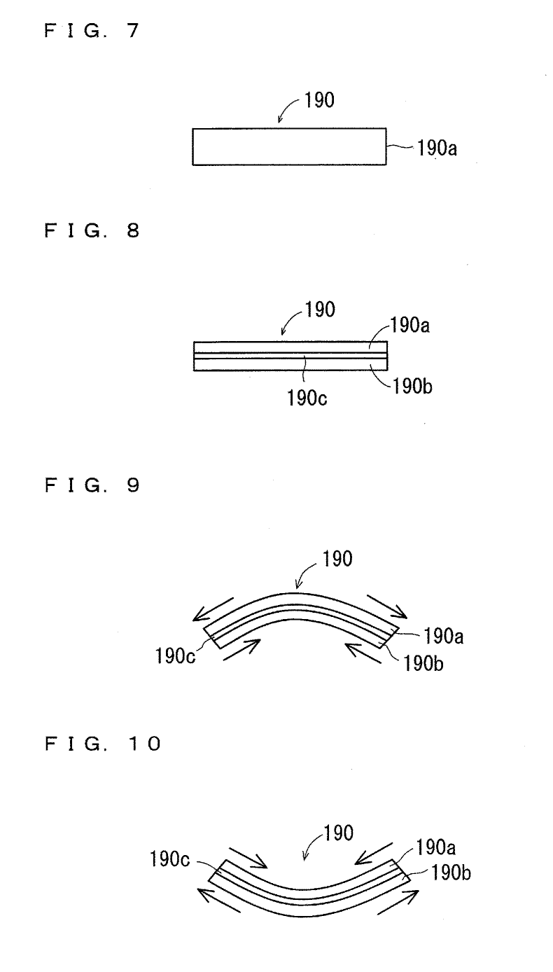

FIGS. 7 and 8 respectively illustrate a top view and a side view showing a structure of the piezoelectric vibrator 190. As illustrated in FIGS. 7 and 8, the piezoelectric vibrator 190 has a long shape in one direction. Specifically, the piezoelectric vibrator 190 has a long and narrow rectangular shape in the plan view. The piezoelectric vibrator 190 has, for example, a bimorph structure. The piezoelectric vibrator 190 includes a first piezoelectric ceramic plate 190a and a second piezoelectric ceramic plate 190b which are bonded to each other with a shim material 190c therebetween.

In the piezoelectric vibrator 190, when a positive voltage is applied to the first piezoelectric ceramic plate 190a and a negative voltage is applied to the second piezoelectric ceramic plate 190b, the first piezoelectric ceramic plate 190a extends along the longitudinal direction and the second piezoelectric ceramic plate 190b contracts along the longitudinal direction. Accordingly, as illustrated in FIG. 9, the piezoelectric vibrator 190 is bent into a convex shape with the first piezoelectric ceramic plate 190a being the outside.

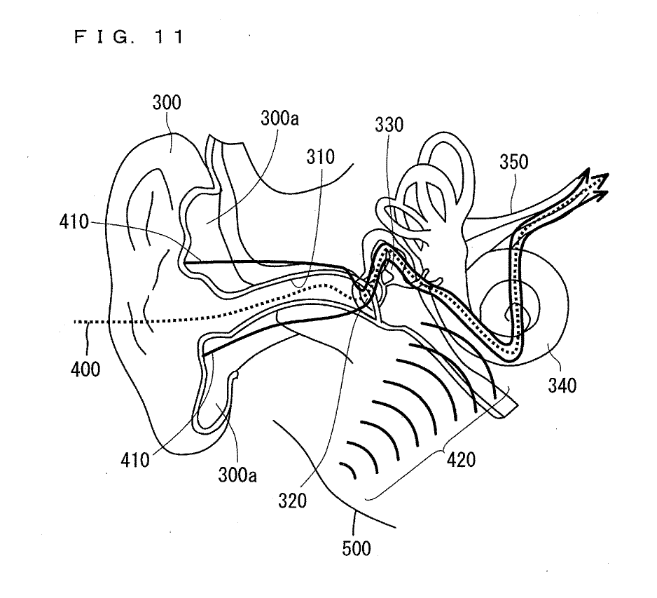

In contrast, in the piezoelectric vibrator 190, when a negative voltage is applied to the first piezoelectric ceramic plate 190a and a positive voltage is applied to the second piezoelectric ceramic plate 190b, the first piezoelectric ceramic plate 190a contracts along the longitudinal direction and the second piezoelectric ceramic plate 190b extends along the longitudinal direction. Accordingly, as illustrated in FIG. 10, the piezoelectric vibrator 190 is bent into a convex shape with the second piezoelectric ceramic plate 190b being the outside.

The piezoelectric vibrator 190 vibrates while being bent along the longitudinal direction by alternately taking the state of FIG. 9 and the state of FIG. 10. The controller 100 allows the piezoelectric vibrator 190 to vibrate while being bent along the longitudinal direction by applying an alternating current (AC) voltage in which the positive voltage and the negative voltage alternately appear at an area between the first piezoelectric ceramic plate 190a and the second piezoelectric ceramic plate 190b.

Only one structure made of the first piezoelectric ceramic plate 190a and the second piezoelectric ceramic plate 190b, which are bonded to each other with the shim material 190c therebetween, is located in the piezoelectric vibrator 190 illustrated in FIGS. 7 to 10. Alternatively, a plurality of the structures may be laminated to each other.

As illustrated in FIGS. 4 and 5, the piezoelectric vibrator 190 having such a structure is disposed on the peripheral end of the inner main surface 21 of the cover panel 2. Specifically, the piezoelectric vibrator 190 is disposed on a central portion in a short-length direction DR2 in the upper-side end portion of the inner main surface 21 of the cover panel 2. The piezoelectric vibrator 190 is disposed such that the longitudinal direction thereof extends along the short-length direction DR2 of the cover panel 2. In this manner, the piezoelectric vibrator 190 vibrates while being bent along the short-length direction DR2 of the cover panel 2. Further, the center of the piezoelectric vibrator 190 in the longitudinal direction corresponds to the center of the upper-side end portion of the inner main surface 21 of the cover panel 2 in the short-length direction DR2.

As illustrated in FIGS. 9 and 10 mentioned above, the center of the piezoelectric vibrator 190 in the longitudinal direction has the largest displacement amount when the piezoelectric vibrator 190 is vibrating while being bent. Therefore, an area in the center in the short-length direction DR2 in the upper-side end portion of the inner main surface 21 of the cover panel 2, which corresponds to the position of the piezoelectric vibrator 190, has the largest displacement amount of bending and vibrating.

Only one structure made of the first piezoelectric ceramic plate 190a and the second piezoelectric ceramic plate 190h, which are bonded to each other with the shim material 190c therebetween, is located in the piezoelectric vibrator 190 illustrated in FIGS. 7 to 10. Alternatively, a plurality of the structures may be laminated to each other. The laminated structure preferably includes greater than or equal to 28 layers, more preferably, greater than or equal to 44 layers since a sufficient vibration can be transmitted to the cover panel 2.

The piezoelectric vibrator 190 may be made of an organic piezoelectric material such as polyvinylidene fluoride and polylactic acid in addition to the piezoelectric ceramic material. Specifically, the piezoelectric vibrator 190 may include, for example, a first piezoelectric plate and a second piezoelectric plate that are laminated to each other and made of a polylactic acid film. A transparent electrode such as indium-tin-oxide (ITO) may be used as an electrode of the piezoelectric plate.

<Generation of Reception Sound>

In the electronic apparatus 1 according to one embodiment, the piezoelectric vibrator 190 causes the cover panel 2 to vibrate through the display panel 120 and the touch panel 130, so that the air conduction sound and the tissue conduction sound are transmitted from the cover panel 2 to the user. In other words, the vibration of the piezoelectric vibrator 190 itself is transmitted to the cover panel 2 through the display panel 120 and the touch panel 130, so that the air conduction sound and the tissue conduction sound are transmitted from the cover panel 2 to the user.

Here, the term “air conduction sound” is a sound recognized in the human brain by the vibration of an eardrum due to a sound wave (air vibration) which enters an external auditory meatus hole (a so-called “ear hole”). On the other hand, the term “tissue conduction sound” is a sound recognized in the human brain by the vibration of the eardrum due to the vibration of an auricle transmitted to the eardrum. Hereinafter, the air conduction sound and the tissue conduction sound will be described in detail.

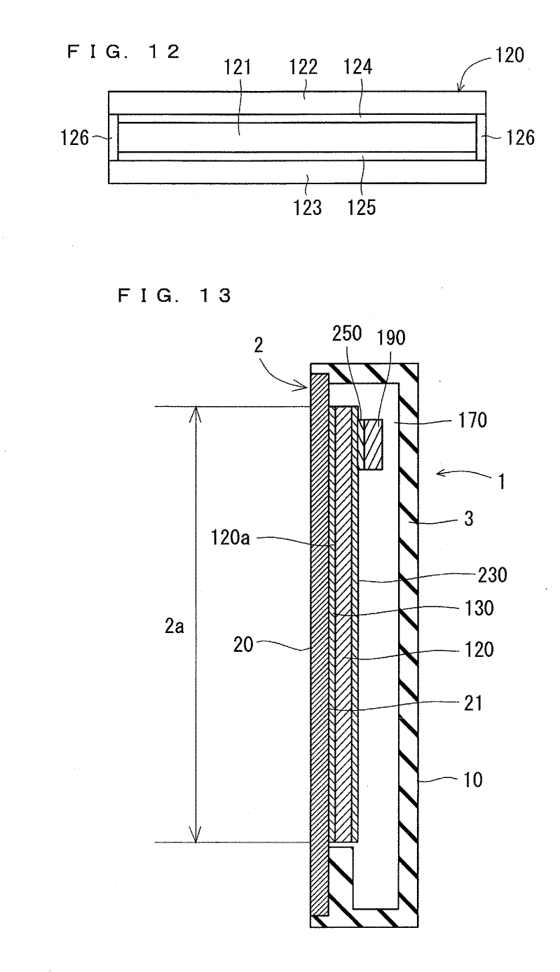

FIG. 11 is a view for describing the air conduction sound and the tissue conduction sound. FIG. 11 illustrates the structure of the ear of the user of the electronic apparatus 1. In FIG. 11, a dotted line 400 indicates a conduction path of a sound signal (sound information) while the air conduction sound is recognized in the human brain. A solid line 410 indicates a conduction path of a sound signal while the tissue conduction sound is recognized in the human brain.

When the piezoelectric vibrator 190 mounted on the cover panel 2 with the display panel 120 and the touch panel 130 therebetween vibrates based on the electric sound signal indicating the reception sound, the vibration is transmitted to the cover panel 2 through the display panel 120 and the touch panel 130, and a sound wave is output from the cover panel 2. When the user moves the cover panel 2 of the electronic apparatus 1 to an auricle 300 of the user by holding the electronic apparatus 1 in a hand, or the cover panel 2 of the electronic apparatus 1 is set to (brought into contact with) the auricle 300 of the user, the sound wave output from the cover panel 2 enters an external auditory meatus hole 310. The sound wave from the cover panel 2 travels through the external auditory meatus hole 310 and causes an eardrum 320 to vibrate. The vibration of the eardrum 320 is transmitted to an auditory ossicle 330 and the auditory ossicle 330 vibrates. In addition, the vibration of the auditory ossicle 330 is transmitted to a cochlea 340 and is converted into an electrical signal in the cochlea 340. The electrical signal is transmitted to the brain by passing through an acoustic nerve 350 and the reception sound is recognized in the human brain. In this manner, the air conduction sound is transmitted from the cover panel 2 to the user.

Further, when the user puts the cover panel 2 of the electronic apparatus 1 to the auricle 300 of the user by holding the electronic apparatus 1 in a hand, the auricle 300 is vibrated by the cover panel 2, which is vibrated by the piezoelectric vibrator 190. The vibration of the auricle 300 is transmitted to the eardrum 320, and thus the eardrum 320 vibrates. The vibration of the eardrum 320 is transmitted to the auditory ossicle 330, and thus the auditory ossicle 330 vibrates. The vibration of the auditory ossicle 330 is transmitted to the cochlea 340 and is converted into an electrical signal in the cochlea 340. The electrical signal is transmitted to the brain through the acoustic nerve 350 and the reception sound is recognized in the brain. In this manner, the tissue conduction sound is transmitted from the cover panel 2 to the user. FIG. 11 also illustrates an auricle cartilage 300a in the inside of the auricle 300.

The tissue conduction sound is different from bone conduction sound (also referred to as “bone tissue conduction sound”). The bone conduction sound is a sound recognized in the human brain by the vibration of the skull and direct stimulation of the inner ear such as the cochlea caused by the vibration of the skull. In FIG. 11, in a case where a jawbone 500 vibrates, the transmission path of the sound signal while the bone conduction sound is recognized in the brain is indicated by a plurality of arcs 420.

As described above, the piezoelectric vibrator 190 appropriately causes the cover panel 2 being the front surface to vibrate through the display panel 120 and the touch panel 130, so that the air conduction sound and the tissue conduction sound can be transmitted from the cover panel 2 to the user of the electronic apparatus 1 in one embodiment. The user can hear the air conduction sound from the cover panel 2 by moving the cover panel 2 close to an ear (auricle). Further, the user can hear the air conduction sound and the tissue conduction sound from the cover panel 2 by bringing the cover panel 2 into contact with an ear (auricle). The structure of the piezoelectric vibrator 190 according to one embodiment is contrived to appropriately transmit the air conduction sound and the tissue conduction sound to the user. Various advantages are achieved by forming the electronic apparatus 1 to transmit the air conduction sound and the tissue conduction sound to the user.

For example, since the user can hear a sound when putting the cover panel 2 to the ear, communication using the electronic apparatus 1 can be performed without much concerning of the position of the electronic apparatus 1 with respect to the ear.

If there is a large amount of ambient noise, the user can make it difficult to hear the ambient sound by strongly putting the cover panel 2 to the ear while turning up the volume of the tissue conduction sound. Accordingly, the user can appropriately perform communication even when there is a large amount of the ambient noise.

In addition, even with earplugs or earphones on his/her ears, the user can recognize the reception sound from the electronic apparatus 1 by putting the cover panel 2 to the ear (more specifically, the auricle). Further, even with headphones on his/her ears, the user can recognize the reception sound from the electronic apparatus 1 by putting the cover panel 2 to the headphones.

The portion of the cover panel 2 on which the piezoelectric vibrator 190 is mounted in the plan view vibrates relatively easily. Thus, the user can easily hear the sound from the cover panel 2 by moving the upper-side end portion (particularly, the central portion in the short-length direction DR2 of the upper-side end portion) of the cover panel 2, on which the piezoelectric vibrator 190 is mounted, close to the ear or by putting the portion to the ear.

As described above, the piezoelectric vibrator 190 is located closer to the rear surface side than the display panel 120 is, and outputs the vibration to the cover panel 2 through the display panel 120 and the touch panel 130. In such a structure, even when the display panel 120 extends parallel to the cover panel 2, the display panel 120 and the piezoelectric vibrator 190 do not interfere (do not come into physical contact) with each other. Thus, the display panel 120 can increase in size in the plan view regardless of the presence of the piezoelectric vibrator 190. This can extend the display portion 2a (display screen). In other words, the structure contributes to a larger screen of the electronic apparatus 1.

Conversely, even when the piezoelectric vibrator 190 extends parallel to the cover panel 2, the piezoelectric vibrator 190 does not interfere with the display panel 120. Thus, the piezoelectric vibrator 190 can increase in size in the plan view regardless of the presence of the display panel 120. This can increase vibration energy generated in the piezoelectric vibrator 190. Therefore, a decrease in vibration (amplitude) of the cover panel 2 due to the vibration passing through the touch panel 130 and the display panel 120 can be suppressed. Furthermore, a decrease in qualities of a voice transmitted from the electronic apparatus 1 to the user can be suppressed. This is conducive to both increasing the screen and maintaining the voice quality.

<Display Panel 120>

According to one embodiment described above, the piezoelectric vibrator 190 outputs the vibration to the cover panel 2 through the display panel 120 and the touch panel 130. Thus, the display panel 120 that easily transmits the vibration to the cover panel 2 is used herein. In other words, a display panel including a display element that emits light itself is used as the display panel 120. For a more particular example, the display panel 120 is, for example, an organic EL panel.

FIG. 12 illustrates an example of a schematic configuration of the display panel 120. FIG. 12 illustrates a section of the display panel 120 including a normal line. The display panel 120 includes, for example, a display element 121 and a pair of substrates 122, 123 sandwiching the display element 121 therebetween. In the example of FIG. 12, the substrate 122 is located closer to the cover panel 2 than the substrate 123 is.

The substrates 122, 123 are, for example, substrates made of resin, and at least the substrate 122 is transparent. Thus, the visible light from the display element 121 can pass through the substrate 122 to the user. For example, flexible substrates may be used as the substrates 122, 123. The substrates 122, 123 are made of, for example, resin, and more particularly, a polymeric material (such as polyethylene terephthalate (PET)). Further, the substrates 122, 123 may be formed into a thin film, for example. The substrates 122, 123 having flexibility (pliability) can be easily bent.

The substrate 122 and the substrate 123 in a pair include an electrode 124 and an electrode 125, respectively. The substrate 122 and the substrate 123 respectively include the electrode 124 and the electrode 125 located on surfaces on the display element 121 side, for example. The substrate 123 includes, for example, a pixel switch (semiconductor switch, which is not shown) located in each pixel, and the pixel switch is switched between ON and OFF to control voltage applied to the electrode (cathode) 125. The electrode 125 may be a transparent electrode (for example, an electrode made of indium tin oxide (IGTO)) or a reflective electrode (for example, an electrode made of metal). The electrode 124 is made of, for example, IGTO and is a transparent electrode. The reason is that the visible light generated in the display element 121 needs to pass through the electrode 124 to the user. A predetermined voltage (display voltage) can be applied to each pixel of the display element 121 located between the electrodes 124 and 125 in this structure.

The display element 121 is an organic EL layer and emits light according to the display voltage. The display element 121 is liquid at room temperature, for example. A well-known organic EL layer may be used as the organic EL layer. For example, the organic EL layer has the functions of transporting carriers (electrons and positive holes) and emitting light. Radical anions (electrons) and radical cations (positive holes) are generated in the organic EL layer by an oxidation-reduction reaction in the electrodes 124, 125. Then, the radical anions and the radical cations are moved (the function of transporting carriers) and collide against each other to generate bases and neutral molecules in an excited state. The neutral molecules disappear to cause light emission (the function of emitting light).

The controller 100 controls the display voltage of each pixel between the electrodes 124, 125 to control an amount of light emission of each pixel. Thus, information (display image) can be displayed on the display portion 2a.

The liquid organic EL layer does not cause disconnection from the electrodes 124, 125, thereby achieving excellent flexibility. However, the flexibility does not need to be exploited in one embodiment. In other words, the display panel 120 may be disposed without being bent.

As illustrated in FIG. 12, a sealing material 126 is located between the pair of the substrates 122, 123. The sealing material 126 seals the display element 121 by surrounding the outer periphery of the display element 121. Thus, the display element 121 is kept between the pair of the substrates 122, 123.

The display panel 120 including the display element 121 that emits light itself is thinner than a liquid crystal display panel, for example. One of the reasons is as follows. That is, the liquid crystal display panel includes a liquid crystal layer as a display element that does not emit light. Thus, the liquid crystal display panel needs a backlight, and an amount of transmitted light for each pixel is controlled by the liquid crystal layer that allows light from the backlight to pass therethrough and/or shields the light. The backlight is located on the liquid crystal display panel opposite to the cover panel 2. The backlight is located between the display panel 120 (the liquid crystal display panel) and the piezoelectric vibrator 190, assuming that FIG. 4 is referred to. Consequently, the piezoelectric vibrator 190 outputs the vibration to the cover panel 2 through the backlight, the display panel 120 (the liquid crystal display panel), and the touch panel 130.

On the other hand, in one embodiment, the display element 121 of the display panel 120 emits light itself, thereby eliminating the need of the backlight. Thus, the structural components between the piezoelectric vibrator 190 and the cover panel 2 can be reduced in number by at least the backlight. In other words, the overall thickness of the structural components between the piezoelectric vibrator 190 and the cover panel 2 can be reduced. Therefore, the vibration of the piezoelectric vibrator 190 can be transmitted to the cover panel 2 more easily than that in the structure including the liquid crystal display panel. Thus, the user can hear the voice from the cover panel 2 more easily. In other words, the qualities of the voice can be improved.

Further, the substrates 122, 123 may be substrates having a film shape, as described above. The substrates having the film shape herein refer to substrates thin enough to have flexibility. Accordingly, the substrates 122, 123 are formed to be thin, so that the vibration from the piezoelectric vibrator 190 can be transmitted to the cover panel 2 more easily. Therefore, the user can hear the voice from the cover panel 2 more easily.

### Second Embodiment

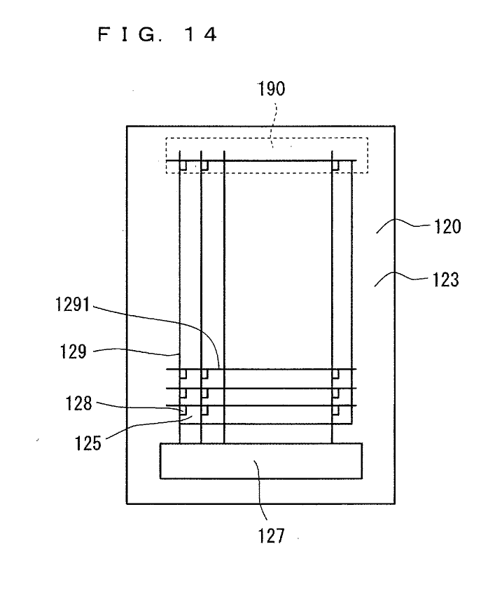

FIG. 13 illustrates another example of a schematic configuration of the electronic apparatus 1. FIG. 13 illustrates the same section as that in FIG. 4. In comparison with the electronic apparatus 1 in FIG. 4, the electronic apparatus 1 in FIG. 13 further includes a metal plate 230. The metal plate 230 has a plate shape. The metal plate 230 is located between the display panel 120 and the piezoelectric vibrator 190. The metal plate 230 is located such that its main surface faces the display panel 120. The metal plate 230 is larger than the piezoelectric vibrator 190 in the plan view, and is equal to or larger than the display panel 120, for example. The metal plate 230 has an elastic coefficient higher than that of the display panel 120 (more specifically, the substrates 122, 123), and is made of, for example, stainless steel or aluminum.

The metal plate 230 is attached to, for example, the main surface of the display panel 120 on the rear surface side with, for example, a bonding material (not shown). The bonding material may be the double-sided tape (such as the OCA tape) or the adhesive (such as the OCR). The piezoelectric vibrator 190 is attached to the main surface of the metal plate 230 on the rear surface side with the bonding material 250. The piezoelectric vibrator 190 outputs the vibration to the cover panel 2 through the metal plate 230, the display panel 120, and the touch panel 130.

First, the piezoelectric vibrator 190 vibrates the metal plate 230 in the structure. Since the metal plate 230 has the elastic coefficient higher than that of the display panel 120 (more specifically, the substrates 122, 123), the vibration is easily transmitted to the entire surface of the metal plate 230. Then, when the metal plate 230 vibrated by the piezoelectric vibrator 190 also vibrates the display panel 120, the metal plate 230 larger than the piezoelectric vibrator 190 can vibrate the display panel 120 through the surface of the metal plate 230 larger than that of the piezoelectric vibrator 190.

Thus, the vibration is transmitted to the cover panel 2 through the larger surface of the metal plate 230, to thereby easily cause the larger surface of the cover panel 2 to vibrate. Therefore, the user can hear the voice from the cover panel 2 more easily even at a location apart from the piezoelectric vibrator 190. Furthermore, the qualities of the voice transmitted from the cover panel 2 to the user can be improved.

Moreover, the metal plate 230 has conductivity, so that the metal plate 230 can shield the display panel 120. For this reason, even when the other electronic components are located on the rear surface side of the metal plate 230 in the electronic apparatus 1, the other electronic components can be less affected by electromagnetic radiation due to the operations of the display panel 120.

### Third Embodiment

A configuration of the electronic apparatus 1 according to a third embodiment is the same as that in the first embodiment or the second embodiment. A drive circuit that drives the display panel 120 is described in the third embodiment. More specifically, the drive circuit drives the pixel switch located in each pixel in the display panel 120. FIG. 14 illustrates a plan view showing an example of a schematic configuration of the display panel 120 and the piezoelectric vibrator 190.

A drive circuit 127 is a circuit for outputting a signal to a pixel switch 128 located in each pixel in the display panel 120. The drive circuit 127 is located on the substrate 123. The drive circuit 127 is electrically connected to a signal line (connected to the pixel switch 128) 129 located on the substrate 123 with, for example, solder or a connector. The signal line 129 comprises a plurality of signal lines that extend parallel to each other at an interval therebetween. Ends of the plurality of signal lines 129 are connected to the drive circuit 127. The drive circuit 127 is electrically connected to a cable (such as a flexible wiring substrate, which is not shown) connected to the controller 100 with solder or a connector. Thus, the controller 100 can input a signal to the signal lines 129.

A plurality of signal lines 1291 that cross the signal lines 129 are also located on the substrate 123. An insulating layer (not shown) is located between the signal lines 129 and the signal lines 1291. The plurality of signal lines 1291 also extend parallel to each other at an interval therebetween. The signal lines 1291 are also connected to the controller 100 with a drive circuit and a cable, which are not shown. Thus, the controller 100 can input a signal to the signal lines 1291.

Each area surrounded by the signal lines 129, 1291 corresponds to a pixel, and the pixel switch 128 is located at each intersection of the signal lines 129, 1291 in the structure.

For example, the signal line 129 is connected to a control terminal of the pixel switch 128, and the signal line 1291 is connected to one terminal of the pixel switch 128. The other terminal of the signal line 1291 is connected to the electrode 125. In this structure, when a signal is input to the signal line 129 to turn the pixel switch 128 ON, a signal input to the signal line 1291 is applied as a display voltage to the electrode 125.

The controller 100 inputs the signal to the signal line 129 to control the pixel switch 128 while inputting the signal to the signal line 1291 to apply the display voltage to the electrode 125.

As illustrated in FIG. 14, the drive circuit 127 is located in a region opposite to the piezoelectric vibrator 190 with respect to the center of the display panel 120 in the plan view. As exemplified in FIG. 14, the piezoelectric vibrator 190 is located on the upper-side end portion of the display panel 120 in the plan view while the drive circuit 127 is located on the lower-side end portion of the display panel 120 in the plan view. This can keep the drive circuit 127 away from the vibration source (the piezoelectric vibrator 190). Thus, the vibration transmitted to the drive circuit 127 can be suppressed. Consequently, a faulty connection due to the vibration can be less likely to occur at a connecting portion between the drive circuit 127 and the substrate 123 or a connecting portion between the drive circuit 127 and the cable.

The signal line 129 does not necessarily need to be connected to the control terminal of the pixel switch 128. The signal line 129 may be connected to the one terminal of the pixel switch 128 while the signal line 1291 may be connected to the control terminal of the pixel switch 128.

The metal plate 230 may be located also in the third embodiment similarly to the second embodiment. In this case, the metal plate 230 may be located in a region other than the region in which the drive circuit 127 is located in the plan view. The reason is that the cover panel 2 can be vibrated through the larger surface of the metal plate 230 while the vibration transmitted to the drive circuit 127 can be suppressed.

In the above description, the case in which the technology of the disclosure is applied to the mobile phones has been described as an example. The technology of the disclosure is also applicable to other electronic apparatuses in addition to the mobile phones such as the smartphones. For example, the technology of the disclosure is also applicable to tablet terminals and wearable mobile electronic apparatuses worn in the arm or the like.

While the electronic apparatus 1 has been described above in detail, the above description is in all aspects illustrative and not restrictive. In addition, various modifications described above are applicable in combination as long as they are not mutually inconsistent. It is understood that numerous modifications which have not been exemplified can be devised without departing from the scope of the present disclosure.

1. An electronic apparatus, comprising:
a cover panel located on a front surface of the electronic apparatus;
a display panel located on a rear surface side of the cover panel and including a display element that emits light itself; and
a vibrator that is located closer to the rear surface side than the display panel is, configured to be vibrated based on a sound signal, and output the vibration to the cover panel through the display panel.

2. The electronic apparatus according to claim 1, wherein
the display panel includes:
an organic electroluminescent (EL) layer serving as the display element; and
substrates sandwiching the organic EL layer.

3. The electronic apparatus according to claim 2, wherein the substrates have a film shape.

4. The electronic apparatus according to claim 1, further comprising a metal plate that is located between the vibrator and the display panel and is larger than the vibrator in a plan view.

5. The electronic apparatus according to claim 1, wherein
the display panel further includes:
a pixel switch located in each pixel; and
a drive circuit configured to drive the pixel switch, and
the drive circuit is located opposite to the vibrator with respect to the center of the display panel in a plan view.
